(19) United States
(12) Patent Application Publication
(10) Pub. No.: US 2025/0021879 A1
(43) Pub. Date: Jan. 16, 2025

(54) Computer-Implemented Method and System for Training a Planning Model

(71) Applicant: Robert Bosch GmbH, Stuttgart (DE)

(72) Inventors: Juergen Mathes, Stuttgart-Moehringen (DE); Markus Mazzola, Tuebingen (DE); Martin Stoll, Renningen (DE); Maxim Dolgov, Renningen (DE)

(21) Appl. No.: 18/767,605

(22) Filed: Jul. 9, 2024

(30) Foreign Application Priority Data
Jul. 12, 2023 (DE) 10 2023 206 602.5

(51) Int. Cl. G06N 20/00

(52) U.S. Cl. CPC G06N 20/00

(57) ABSTRACT

A computer-implemented training method for a planning model is proposed to provide a future behavior of a participant of a given traffic scene based on scene-specific information. As part of the training method, the following steps are performed for at least one training scene and at least one training scene participant in successive simulation steps. With the aid of the planning model to be trained, a future behavior of the participant is predicted. With the aid of a given simulation model and taking into account the predicted behavior of the participant, a future development of the training scene is simulated. The predicted behavior of the participant is compared to the actual behavior of the participant in the temporal development of the training scene. At least one set of latent features is generated in each simulation step, which represents the state of the training scene simulated in that simulation step.

This application claims priority under 35 U.S.C. § 119 to patent application no. DE 10 2023 206 602.5, filed on Jul. 12, 2023 in Germany, the disclosure of which is incorporated herein by reference in its entirety.

The disclosure relates to a computer-implemented training process for a planning model that provides a future behavior of at least one participant of a given traffic scene based on scene-specific information.

Furthermore, the disclosure relates to a computer-implemented system for performing such a training method as well as a computer-implemented method for predicting and/or planning a future behavior of at least one participant of a given traffic scene with the aid of a planning model trained according to the disclosure.

The training method in question here provides that for at least one training scene and at least one participant in the training scene in successive simulation steps; a future behavior of the participant is predicted with the aid of the planning model to be trained, a future development of the training scene is simulated with the aid of a given simulation model and taking into account the predicted behavior of the participant, and the predicted behavior of the participant is compared to the participant's actual behavior in the temporal development of the training scene (Ground Truth).

### BACKGROUND

Learning-based methods, particularly Deep Learning (DL), enable the development of planning models for automated driving (AD) that scale to many real world scenarios. The learning-based methods differentiate between reinforcement learning (RL), where an agent learns by trial and error in simulation, and imitation learning (IL) that learns from demonstrations, such as from trajectories driven by humans.

With imitation learning, the planning model to be trained generates predictive behavior, usually in the form of a trajectory. In most cases, only an initial section of this trajectory is run or compared to a trajectory that has actually been run, because a new trajectory is replanned at regular intervals. It has been shown that the desired performance of the planning model during application, the closed-loop behavior, is generally not achieved with naive IL, so-called behavior cloning. In this case, learning only takes place on the basis of the trajectories predicted in the individual time steps, while the replanning aspect is completely ignored. With behavior cloning, small errors can accumulate that the planning model never sees in the data during training and consequently does not learn to reduce them. To counteract this, differentiable simulation is becoming increasingly popular, as described, for example, in Howell et al., “Dojo: A Differentiable Simulator for Robotics”. Differentiable simulation can take closed-loop behaviors into account in the learning process. The idea behind using the differentiable simulation is explained in more detail below in conjunction with FIG. 1A and FIG. 1B.

FIGS. 1A and 1B each show a time axis labeled t with a plurality of successive time steps of a predetermined duration, as well as the time course of an actual driven trajectory 2 of a vehicle 1, which is also referred to as ground truth.

FIG. 1A illustrates the mode of action of a classic imitation learning (IL) method. FIG. 1A shows a trajectory 10 that has been predicted by a planning model for the vehicle 1 and extends over five time steps. This predicted trajectory 10 is evaluated by comparison with ground truth 2 by determining the deviation between the predicted trajectory 10 and ground truth 2 at a given point in time as loss 3.

In contrast, deviations may be accumulated over time in the differentiable simulation illustrated by FIG. 1B. To this end, the future development of the training scene is simulated with the aid of a given simulation model and taking into account the predicted behavior of the participant in successive time steps. In addition, trajectories 10, 11, 12, 13 predicted in the preceding time step are replanned in each time step—trajectories 11, 12, 13, 14—taking into account the result of the simulation. The result of this gradual simulation is shown in FIG. 1B in the form of a simulated trajectory 4. FIG. 1B shows that the prediction in each of the individual time steps—trajectories 11, 12, 13, 14—was based on a starting point on the simulated trajectory 4. The individual trajectories 11, 12, 13, 14 are evaluated here, as in the case of FIG. 1A by comparison with ground truth 2. The resulting losses are shown here—analogous to FIG. 1A—by unspecified double arrows. The simulated trajectory 4 is passed on to the planning model to be trained as a differentiable learning signal via the simulation model. As a result, the planning model sees more of its influence on the system, can learn from it and thereby shows greater stability and higher performance in driving behavior or closed-loop operation relative to ground truth 2.

Regardless of the IL methods described above for training AD planning models, the use of latent features from DL-based perception and environmental modeling has established itself in the planning and prediction for AD applications. Namely, it has been shown that a relatively large information content can be provided with the aid of these latent features, including, for example, uncertainties from environmental perception, which has a positive effect on the quality of the prediction and planning. Thus, a planning component may utilize uncertainty information from latent features of perception networks to initiate suitable, careful maneuvers when objects have not been fully detected and/or classified by the perception networks. This is not possible if a separation is made between the perception modules and the planning and prediction component and the planning and predictive component is substantially only provided with object information, such as an object list, map, occupancy grids, etc., of the current traffic scene, without any additional information about the reliability of the object information.

### SUMMARY

An advantageous further development of imitation learning with differentiable simulation is proposed. In particular, measures are proposed that enable the use of differentiable simulation in the training of planning models that use utilize latent features from perception as input data.

According to the disclosure, at least one set of latent features is generated in each simulation step, which represents the state of the training scene simulated in that simulation step. This set of latent features is then used as a basis for predicting the behavior of the participant in the following simulation step.

The disclosure is based on the idea of also using imitation learning with differentiable simulation for the training of planning models that generate a behavior planning for individual participants of a traffic scene based on latent features as a scene representation.

This is countered by the fact that only latent features representing a given state of the training scene can be generated based on the training data, but not latent features representing a later, updated state of the training scene. The planning model to be trained therefore only has latent features available for the initial prediction in the first simulation step of the differentiable simulation. In the subsequent simulation steps, these latent features can no longer be used sensibly for the prediction, because they do not take the further development of the training scene into account. According to the disclosure, this problem is solved by the fact that in addition to simulating the temporal development of a training scene in each simulation step, at least one set of latent features is also generated, which represents the respective simulated state of the training scene. As a result, the planning model to be trained can be provided with latent features in each subsequent simulation step representing the respective simulated state of the training scene.

The training data, which are provided for the training method according to the disclosure should include at least a description of the at least one training scene and a description of the actual behavior of the participant during the temporal development of the training scene, hereinafter referred to as ground truth.

The description of a training scene preferably includes scene-specific information that has been aggregated at a given point in time. Scene-specific information from the training scene can come from both onboard and off-board, infrastructure-based sources of information. As a rule, the scene-specific information is data recorded by camera sensors, lidar sensors and/or radar sensors. In addition, scene-specific information may have also been recorded using road users' inertial sensors. The scene-specific information is often supplemented by GPS data and environmental information, e.g. weather data and road condition data. The scene-specific information is aggregated at a given timepoint and accordingly comprises the current sensor and other data at that timepoint. However, the information can also comprise sensor data and other data collected over a specified time period until the given timepoint.

Alternatively or in addition to the scene-specific information, the training data may also include an environmental model as a description of the training scene derived from scene-specific information aggregated at a given point in time. By evaluating scene-specific information, objects in the training scene can be detected and classified in order to create object lists for the training scene. These may be enriched with information about the state and/or state changes of the objects. Occupancy grids for the training scene can be generated and refined by combining them with map information. Such occupancy grids may also be supplemented with information about the infrastructure and/or road topography of the training scene.

The behavior of a participant of a traffic scene is often described in the form of trajectory data, particularly by a temporal sequence of position and/or movement information of the participant. In addition to this, trajectory data may also include other information, such as information about the orientation of the participant. In principle, however, the behavior of a participant can also be described in another form. Advantageously, the same description is chosen for the description of the actual behavior of the participant during the temporal development of the training scene, i.e., for the description of the ground truth, as for the predicated behavior of the participant.

In an advantageous variant of the training method according to the disclosure, an initial environmental model for the given training scene is provided and then updated in time in the successive simulation steps. If the training data does not already include a description of the training scene in the form of an environmental model, but rather the description of the training scene is in the form of scene-specific information, then the initial environmental model can, for example, be simply generated with a DL perception module.

Furthermore, it proves advantageous if at least one initial set of latent features is generated as a representation of the given training scene based on the training data in order to use this initial set of latent features as a basis for predicting the behavior of the participant in the first simulation step. If the training data includes scene-specific information as a description of the training scene, the initial set of latent features may be generated with the aid of a DL perception module. However, a dedicated feature generator may also be used, which generates the initial set of latent features based on an environmental model of the training scene. It is essential here that the planning model to be trained is provided with latent features for the prediction in the first simulation step. According to the disclosure, in the subsequent simulation steps, the planning module to be trained uses the respective latent features generated in the previous simulation step for predicting the behavior of the participant.

Advantageously, the prediction in the further simulation steps also takes into account the behavior simulated for the participant in the previous simulation step. If the behavior is predicted in the form of trajectory data, the position of the participant determined in the previous simulation step at the time of the new behavior prediction may then advantageously be used as the starting point for the newly predicted trajectory.

According to the disclosure, at least one set of latent features is generated in each simulation step of the training method according to the disclosure, which represents the state of the training scene simulated in that simulation step.

In a variant of the training method according to the disclosure, the latent features are predicted in the latent space, i.e. based on latent features representing the respective state of the training scene. Therefore, this prediction of latent features in the first simulation step is based on the initial set of latent features generated based on the training data. The prediction of latent features in the further simulation steps is then based on the set of latent features of the preceding simulation step.

In an advantageous further development of this variant, the state of the environmental model of the training scene is also taken into account in the respective simulation step when predicting the latent features.

In a further variant of the training method according to the disclosure, the latent features are generated in the individual simulation steps exclusively on the basis of the current state of the training scene or the environmental model of the training scene.

If the behavior of the participant is predicted in the form of trajectory data, i.e., as a sequence of prediction times of a predetermined prediction interval, then the predicted behavior of the participant may be continuously interpolated between the prediction times for comparison with ground truth. This proves to be particularly advantageous if the simulation steps and the prediction interval are not equal in length.

The planning model to be trained generally includes adaptable parameters that are optimized as part of the training method. For this purpose, the behavior of the participant predicted in the individual simulation steps is compared with ground truth in each case and a loss is determined based on the deviation determined. The parameters of the planning model are then modified to successively reduce the loss. It is of particular advantage if the comparison results from several simulation steps are taken into account in each case. This ensures that the planning model learns not only by comparison with ground truth, but also from its influence on the system.

In addition to the training method described above, a corresponding computer-implemented system for training a planning model is also disclosed, as well as a method for predicting and/or planning a future behavior of at least one participant of a given traffic scene, in which a planning model trained in this way is used. The system according to the disclosure and the prediction/planning method according to the disclosure are explained in more detail below in connection with the figures.

### BRIEF DESCRIPTION OF THE DRAWINGS

The prior art was discussed above with reference to FIGS. 1A and 1B.

FIG. 1A illustrates the mode of action of a classic imitation learning (IL) method.

FIG. 1B illustrates the mode of action of an IL method with differentiable simulation.

The measures according to the disclosure as well as preferred embodiments and further developments of the disclosure are explained in more detail below on the basis of FIGS. 2 to 6.

FIG. 2 illustrates the mode of action of the training method according to the disclosure as well as the interaction of the essential components of a system according to the disclosure for training a planning model.

FIG. 3 illustrates a first method variant for generating latent features in the individual simulation steps of the training method according to the disclosure.

FIG. 4 illustrates a first method variant for generating latent features in the individual simulation steps of the training method according to the disclosure.

FIG. 5 illustrates a method variant for generating an initial set of latent features as a representation a given training scene.

FIG. 6 illustrates the use of a planning model trained according to the disclosure to predict and/or plan a future behavior of at least one participant of a given traffic scene.

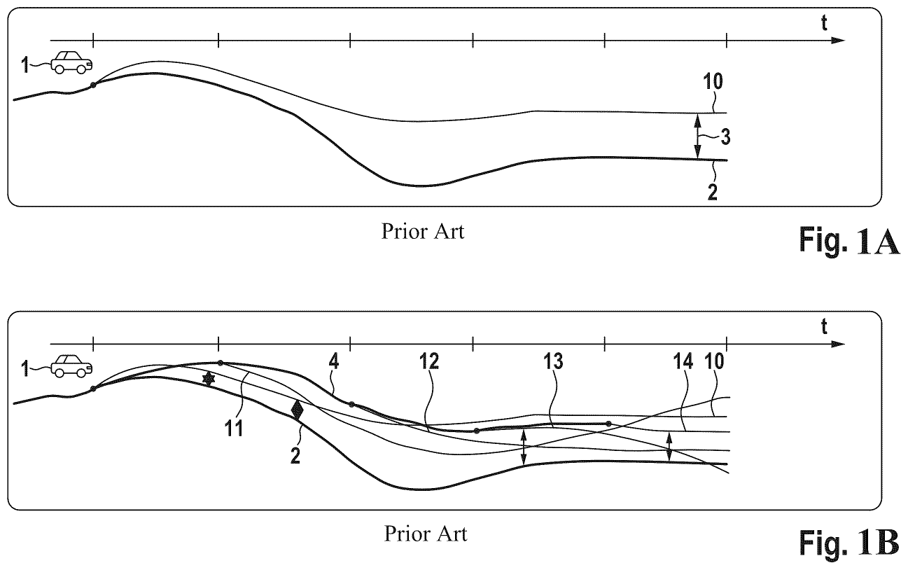

### DETAILED DESCRIPTION

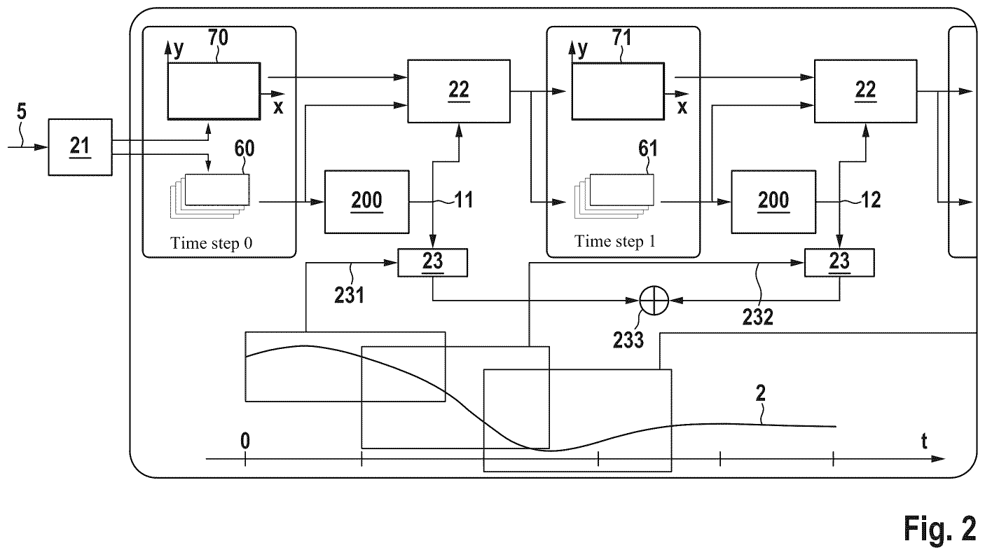

The block diagram in the upper half of FIG. 2 shows the components of a computer-implemented system according to the disclosure over the course of training a planning model 200 comprising at least one neural network. The weights of this neural network are to be optimized as part of the training procedure. The course of the training over time is illustrated with the aid of time axis t in the lower half of FIG. 2. On the time axis t, several successive time steps of a predetermined duration are drawn, starting with an initial time step 0. A ground truth trajectory 2 is recorded over the time axis t, which represents the time course of a trajectory 2 actually driven by a vehicle in a given training scene. The planning model 200 is to be trained for the behavior of this vehicle.

The Ground truth trajectory 2 is part of a training sample which also includes training data for describing a training scene at a given point of time. In the exemplary embodiment described herein, scene-specific information 5 is provided to describe the training scene, which information have been aggregated at a given point in time.

At the beginning of the training, in the initial time step 0, the scene-specific information 5 is fed to a perception module 21, where it is mapped to at least one initial set of latent features 60 using a backbone network component. The perception module 21 thus acts here as a feature generator that generates at least one initial set of latent features 60 representing the given training scene. Furthermore, the perception module 21 here comprises a DL component that generates an initial environmental model 70 of the given training scene based on the scene-specific information 5 and/or the latent features 60. This can be, for example, an object level representation, a 3D or 2D occupancy grid, a map, or a visibility grid.

The block diagram of FIG. 2 illustrates that the planning model 200 to be trained is incorporated into the training system via corresponding interfaces. Thus, the initial set of latent features 60 is provided to the planning model 200 via corresponding interfaces. In addition, the initial set of latent features 60 is fed to a simulation module 22 along with the data from the initial environmental model 70.

In the first time step after the initial time step 0, the planning model 200 uses the initial set of latent features 60 to predict a behavior of the vehicle, here in the form of a trajectory. The result 11 of this first prediction is provided to the simulation module 22, which then simulates the future development of the training scene in a first simulation step, taking into account the predicted behavior 11 of the vehicle. The result of this simulation is an environmental model 71, which is updated starting from the initial environmental model 70.

According to the disclosure, the simulation module 22 also generates at least one set of latent features 61, which represents the state of the training scene simulated in the first simulation step. For this purpose, the simulation module in the embodiment of the disclosure shown here uses both the latent features 60 or 61 as well as information of the environmental model 70 or 71 from the previous simulation step in the individual simulation steps.

The set of latent features 61 generated by the simulation module 22 is then fed back to the planning model 200 via corresponding system interfaces. As a result, latent features 61 representing the currently simulated state of the training scene are available to the planning model 200 for prediction in the next simulation step.

Only the first and second simulation steps with the prediction results 11 and 12 are shown here. However, the method described above can be repeated for any number of simulation steps, since the simulation module 22 according to the disclosure generates at least one set of latent features in each simulation step, which represents the state of the training scene simulated in this simulation step, and this generated set of latent features is used as the basis for predicting the behavior of the participant in the following simulation step.

The prediction results 11 and 12 of the individual simulation steps are compared at least in sections with the aid of a comparison module 23 with ground truth trajectory 2, which is indicated here by arrows 231 and 232. A comparison result is determined in each case. The weights of the planning model 200 are modified as a function of the results of the comparison between the predicted behavior of the participant 11 or 12 and ground truth 2. The linking symbol 233 in FIG. 2 illustrates that the comparison results from several simulation steps are taken into account in each case.

The differentiable simulation for planning and prediction explained above in connection with FIG. 2 is structured as follows. First, for a driving situation or traffic scene given in the form of training data, the DL planning or DL prediction model to be trained generates an output, for example, control commands to the vehicle or a trajectory for a trajectory controller, based on latent features. Second, in a simulation step, the state for the participants in the scene is updated with the aid of a simulation model and while taking into account the planning/prediction model output. In addition, latent features representing the simulated travel situation are generated. Third, the simulated driving situation is assumed to be the current state and one jumps to step 1 if the desired duration of the simulation has not yet been reached.

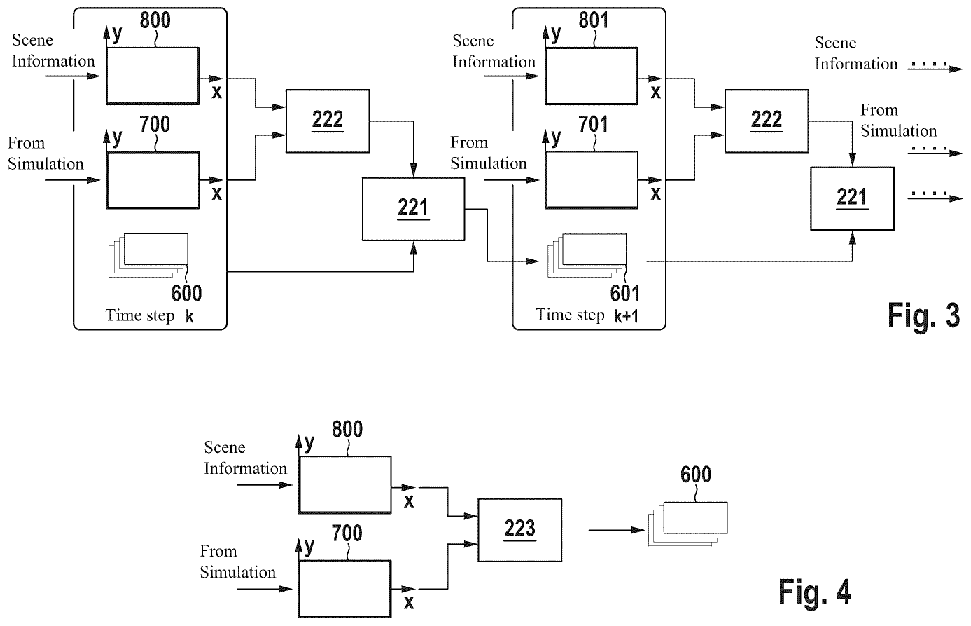

In the method variant shown in FIG. 3, the latent features are generated in the individual simulation steps of the training method according to the disclosure by direct prediction in the latent space.

As in the exemplary embodiment shown in FIG. 2, latent features 600 are available to the simulation module in each simulation step in this method variant—the initial set of latent features in the first simulation step and the set of latent features generated in the previous simulation step in the subsequent simulation steps. In addition, the simulation module is equipped with a DL component 221 that predicts new latent features 601 for the following simulation step, based on these latent features 600. For example, a correspondingly configured transformer with CNN decoder can be used. In addition, information about the state of the environmental model 700, 701 of the training scene and map information 800, 801 are available to the simulation module in each simulation step from the previous simulation step. This information 700, 800 and 701, 801 is processed here with the aid of a graph encoder 222 of the simulation module, so that it can be taken into account when predicting the latent features with the aid of the DL module 221.

Accordingly, in this method variant, a DL model is used, which predicts the latent features. The latent features from the previous simulation step are available as input for the model, as well as other data, such as information about the state and/or the state change of the driving situation. The information about the driving scene may also include information about the road topology in addition to the simulated objects. It is even conceivable that the information about the driving scene will include sensory information such as simulated lidar reflexes, for example. The most appropriate DL topologies (Feed Forward NNs, Convolutional NNs, Graph NNs, Transformer NNs) are used for the prediction of the latent features. FIG. 3 shows an example encoder-decoder architecture.

FIG. 4 illustrates another option for generating latent features in the individual simulation steps of the training method according to the disclosure.

In this approach, the latent features 600 are generated from the current system state using an encoder decoder architecture 223, here from the state of the environmental model 700 in the respective simulation step and map information 800. In contrast to the previous approach, no latent features are predicted here. Advantageously, such a generation of the latent features 600 can be trained directly from recorded real data, e.g., as a GAN (Generative Adversarial Network) or a VAE (Variational Autoencoder).

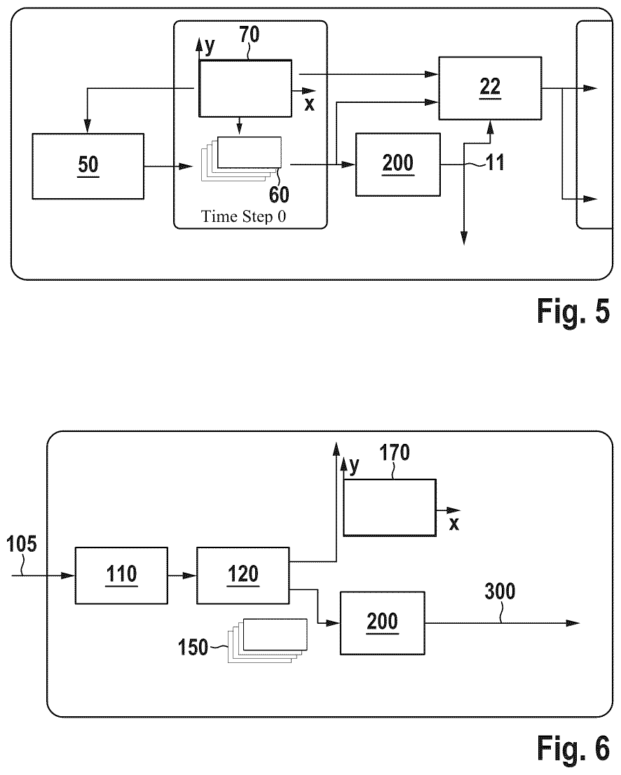

In the embodiment of the disclosure depicted in FIG. 2, the initial set of latent features 60 is generated based on scene-specific training data 5 using a backbone network component of a perception module 21. However, an initial set of latent features 60 may also be generated using a dedicated feature generator 50 based on an initial environment model 70 of the training scene, for example if no scene-specific information and/or backbone network is available to generate “real” latent features. This is shown in FIG. 5.

FIG. 6 illustrates the use of a planning model 200 trained according to the disclosure for predicting and/or planning a future behavior of at least one participant of a given traffic scene. For this purpose, scene-specific information 105 is aggregated at a measurement point. The scene-specific information 105 is collected and preprocessed in a preliminary stage 110. Latent features 150 are then generated as a representation of the current traffic scene using a downstream perception module 120. These latent features 150 are used here on the one hand to generate an environmental model 170 and, on the other hand, as input for the planning model 200. Based on the latent features 150, the planning model 200 then generates a prediction 300, which can either be used directly to control the actuators of the vehicle or can also be used as a basis for further planning steps.

What is claimed is:

1. A computer-implemented training method for a planning model that provides a future behavior of at least one participant of a given traffic scene based on scene-specific information, the method comprising:
as part of the training method, for at least one training scene and at least one training scene participant in successive simulation steps:
predicting, based on a planning model to be trained, a future behavior of the participant;
simulating, using a given simulation model and based on the predicted future behavior of the participant, a future development of the training scene; and
comparing the predicted future behavior of the participant to an actual behavior of the participant in a temporal development of the training scene,
wherein, in each simulation step, at least one set of latent features is generated representing a state of the training scene simulated in the corresponding simulation step, and
wherein the prediction of the future behavior of the participant in a following simulation step is based on the generated set of latent features.

2. The training method according to claim 1, wherein:
training data is provided, and
the provided training data comprises (i) a description of the at least one training scene including scene-specific information that has been aggregated at a given point in time and/or including an environmental model that has been derived from the scene-specific information aggregated at the given point in time, and (ii) a description of the actual behavior of the participant during the temporal development of the training scene.

3. The training method according to claim 2, wherein:
an initial environmental model for the at least one training scene is provided based on the provided training data, and
the initial environmental model is updated in the successive simulation steps.

4. The training method according to claim 2, wherein:
based on the provided training data, at least one initial set of latent features is generated as a representation of the at least one training scene, and
the future behavior of the participant in the first simulation step is predicted based on the initial set of latent features.

5. The training method according to claim 4, wherein the future behavior of the participant in further simulation steps is based on a behavior simulated for the participant of a previous simulation step.

6. The training method according to claim 5, wherein:
the generation of the at least one set of latent features in a first simulation step is based on the at least one initial set of latent features, and
the generation of at least one set of latent features in the further simulation steps is based on the respective set of latent features of the previous simulation step.

7. The training method according to claim 3, wherein the at least one set of latent features in individual simulation steps are generated based on a state of the environmental model of the at least one training scene in the respective simulation step.

8. The training method according to claim 1, wherein:
the future behavior of the participant is respectively predicted for a sequence of prediction times of a predetermined prediction interval, and
the predicted future behavior of the participant is continuously interpolated for comparison with ground truth between the prediction times.

9. The training method according to claim 8, wherein the future behavior of the participant is predicted as trajectory data.

10. The training method according to claim 1, wherein:
the planning model to be trained comprises adaptable parameters optimized as part of the training method,
the adaptable parameters of the planning model are modified as a function of results of the comparison between the predicted future behavior of the participant and the actual behavior, and
the adaptable parameters are modified based on the results from several simulation steps.

11. A computer-implemented system for training a planning model that predicts a future behavior of at least one participant of a given traffic scene based on scene-specific information, for training a planning model, the system comprising:
a processor configured to:
receive training data describing (i) at least one training scene with at least one participant at a given point in time, and (ii) an actual behavior of the participant during a temporal development of the at least one training scene,
generate at least one initial set of latent features representing the at least one training scene using a feature generator implemented by the processor,
incorporate a planning model to be trained using an interface operably connected to the processor,
simulate a future development of the at least one training scene in successive simulation steps using a simulation module implemented by the processor, wherein each simulation step is based on a behavior of the participant predicted by the planning model to be trained and at least one set of latent features is generated representing a state of the at least one training scene simulated in the corresponding simulation step, and
compare the predicted behavior of the participant with ground truth and modify parameters of the planning model as a function of a comparison result using a comparison module implemented by the processor.

12. A computer-implemented method for predicting and/or planning a future behavior of at least one participant in a given traffic scene, the method comprising:
aggregating scene-specific information at a measurement point in order to generate at least one set of latent features as a representation of the given traffic scene based on the scene-specific information; and
predicting the future behavior of the at least one participant using a planning model that has been trained according to the method of claim 1.
